(19) United States
(12) Patent Application Publication
(10) Pub. No.: US 2026/0157210 A1
(43) Pub. Date: Jun. 4, 2026

(54) SEMICONDUCTOR DEVICE AND METHOD FOR FABRICATING THE SAME

(71) Applicant: SAMSUNG ELECTRONICS CO., LTD., Suwon-si (KR)

(72) Inventors: Jun Kyoung LEE, Suwon-si (KR); Ju Bin SEO, Suwon-si (KR); Ho-Jin LEE, Suwon-si (KR); Dong-Chan LIM, Suwon-si (KR); Joo Hee JANG, Suwon-si (KR)

(73) Assignee: SAMSUNG ELECTRONICS CO., LTD., Suwon-si (KR)

(21) Appl. No.: 19/258,443

(22) Filed: Jul. 2, 2025

(30) Foreign Application Priority Data
Dec. 2, 2024 (KR) 10-2024-0176202

(51) Int. Cl. H01L 23/00

(52) U.S. Cl. CPC H10W 72/019; H10W 72/921; H10W 72/923; H10W 72/934; H10W 72/952; H10W 90/792

(57) ABSTRACT

A semiconductor device includes a first semiconductor chip having a first pad structure and a second semiconductor chip having a second pad structure. The first pad structure and the second pad structure are bonded to each other in a first direction. The first pad structure includes a first filling conductive film and a second filling conductive film. The first filling conductive film includes a first portion that overlaps the second filling conductive film in the first direction, and a second portion that overlaps the second filling conductive film in a second direction intersecting the first direction. A first height of the first portion in the first direction is greater than a thickness of the second portion in the second direction, and an electrical conductivity of the second filling conductive film is greater than the electrical conductivity of the first filling conductive film.

### CROSS-REFERENCE TO RELATED APPLICATION

This application claims priority from Korean Patent Application No. 10-2024-0176202 filed on Dec. 2, 2024 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a semiconductor device and a method for fabricating the same. More specifically, the present disclosure relates to a semiconductor device having a bonding structure and a method for fabricating the same.

### Description of the Related Art

In order to improve the degree of integration and performance of a semiconductor device, a semiconductor device having a bonding structure has been proposed. The bonding structure means a structure in which an upper chip and a lower chip are connected by a bonding manner. The bonding manner may mean, for example, a manner in which a bonding pad formed on the uppermost metal layer of the upper chip is connected to a bonding pad formed on the uppermost metal layer of the lower chip.

Meanwhile, as electronic products are required to be miniaturized, an aspect ratio of the bonding pad is constantly increasing. Therefore, there is a problem that defects such as a seam and a void occur in the bonding pad, resulting in a decrease in yield.

### SUMMARY

Aspects of the present disclosure provide a semiconductor device having improved yield and performance.

Aspects of the present disclosure also provide a method for fabricating a semiconductor device having improved yield and performance.

However, aspects of the present disclosure are not restricted to the one set forth herein. The above and other aspects of the present disclosure will become more apparent to one of ordinary skill in the art to which the present disclosure pertains by referencing the detailed explanation of the present disclosure given below.

According to an aspect of the present disclosure, there is provided a semiconductor device comprising a first semiconductor chip and a second semiconductor chip. The first semiconductor chip includes a first substrate, a first semiconductor element layer on the first substrate, a first inter-wiring insulating film on the first semiconductor element layer, a first wiring structure in the first inter-wiring insulating film, and a first pad structure on the first wiring structure. The second semiconductor chip includes a second substrate, a second semiconductor element layer on the second substrate, a second inter-wiring insulating film on the second semiconductor element layer, a second wiring structure in the second inter-wiring insulating film, and a second pad structure on the second wiring structure. The first pad structure and the second pad structure are bonded to each other in a first direction. The first pad structure includes a first filling conductive film and a second filling conductive film that are sequentially disposed on the first wiring structure. The first filling conductive film includes a first portion that overlaps the second filling conductive film in the first direction, and a second portion that overlaps the second filling conductive film in a second direction intersecting the first direction. A first height of the first portion in the first direction is greater than a thickness of the second portion in the second direction, and an electrical conductivity of the second filling conductive film is greater than the electrical conductivity of the first filling conductive film.

According to an aspect of the present disclosure, there is provided a semiconductor device comprising a first semiconductor chip and a second semiconductor chip. The first semiconductor chip includes a first substrate, a first semiconductor element layer on the first substrate, a first inter-wiring insulating film on the first semiconductor element layer, a first wiring structure in the first inter-wiring insulating film, and a first pad structure on the first wiring structure. The second semiconductor chip includes a second substrate, a second semiconductor element layer on the second substrate, a second inter-wiring insulating film on the second semiconductor element layer, a second wiring structure in the second inter-wiring insulating film, and a second pad structure on the second wiring structure. The first pad structure and the second pad structure are bonded to each other. The first pad structure includes a first filling conductive film and a second filling conductive film that are sequentially disposed on the first wiring structure. An aspect ratio of the first pad structure is 2 to 10. A ratio of a first height from a lowermost surface of the first filling conductive film to a lowermost surface of the second filling conductive film to a second height from the lowermost surface of the second filling conductive film to an uppermost surface of the second filling conductive film is 1:4 to 3:2. An electrical conductivity of the second filling conductive film is higher than that of the first filling conductive film.

According to an aspect of the present disclosure, there is provided a semiconductor device comprising a first semiconductor chip and a second semiconductor chip bonded to each other. The first semiconductor chip includes a first substrate, a first semiconductor element layer on the first substrate, a first inter-wiring insulating film on the first semiconductor element layer, a first wiring structure connected to the first semiconductor element layer, in the first inter-wiring insulating film, a first bonding insulating film on the first inter-wiring insulating film and a first pad structure that penetrates the first bonding insulating film and is connected to the first wiring structure. The second semiconductor chip including a second substrate, a second semiconductor element layer on the second substrate, a second inter-wiring insulating film on the second semiconductor element layer, a second wiring structure that is connected to the second semiconductor element layer, in the second inter-wiring insulating film, a second bonding insulating film that is bonded to the first bonding insulating film, on the second inter-wiring insulating film and a second pad structure that penetrates the second bonding insulating film, is connected to the second wiring structure, and bonded to the first pad structure. The first inter-wiring insulating film and the first bonding insulating film include a pad trench that extends from a bonding surface between the first semiconductor chip and the second semiconductor chip toward the first wiring structure. The first pad structure includes a barrier conductive film extending along a profile of a side surface and a lower surface of the pad trench, a first filling conductive film that fills a part of the pad trench on the barrier conductive film, and a second filling conductive film that fills another part of the pad trench on the first filling conductive film. A gap-fill capability of a first metal element contained in the first filling conductive film is superior to the gap-fill capability of a second metal element contained in the second filling conductive film, and an electrical conductivity of the second filling conductive film is higher than the electrical conductivity of the first filling conductive film.

### BRIEF DESCRIPTION OF DRAWINGS

The above and other aspects and features of the present disclosure will become more apparent by describing in detail embodiments thereof with reference to the attached drawings, in which:

FIG. 1 is a schematic exploded perspective view illustrating a semiconductor device according to some embodiments.

FIG. 2 is a schematic cross-sectional view illustrating the semiconductor device of FIG. 1.

FIG. 3 is an enlarged view illustrating a region R of FIG. 2.

FIG. 4 is an illustrative plan view illustrating a first pad structure of FIG. 3.

FIGS. 5a to 5f are enlarged views illustrating various alternative configurations of the region R of FIG. 2 according to some embodiments.

FIGS. 6 to 12 are diagrams of intermediate structures corresponding to intermediate steps of a method for fabricating a semiconductor device according to some embodiments.

### DETAILED EXPLANATION OF THE EMBODIMENTS

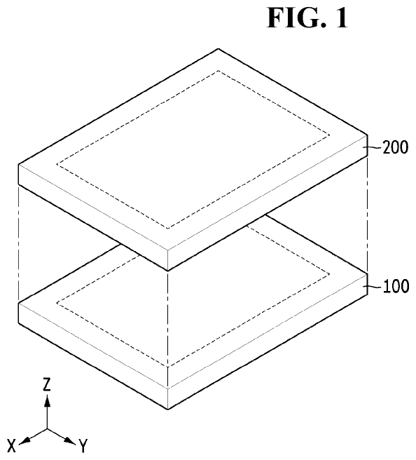

Hereinafter, semiconductor devices according to illustrative embodiments will be described referring to FIGS. 1 to 5f.

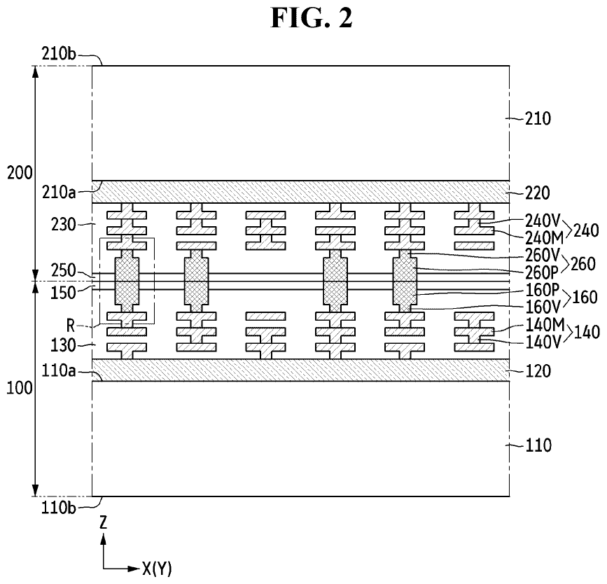

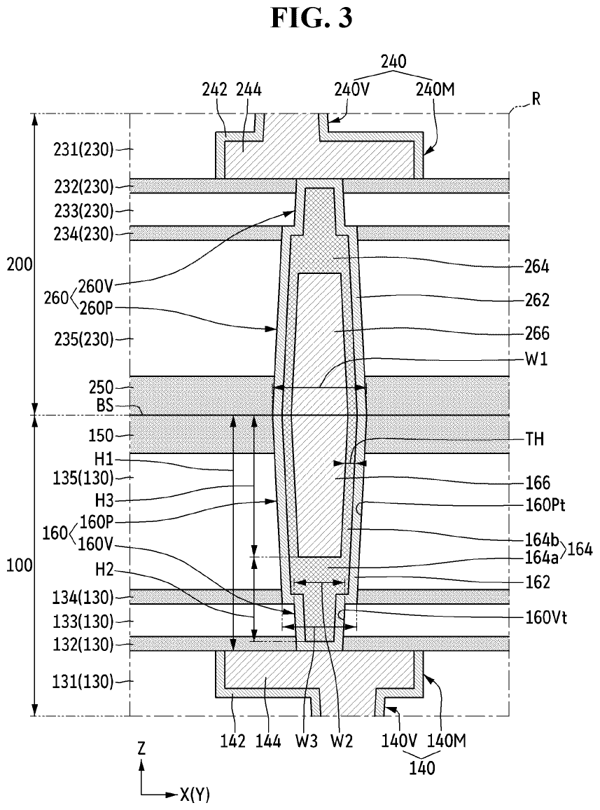

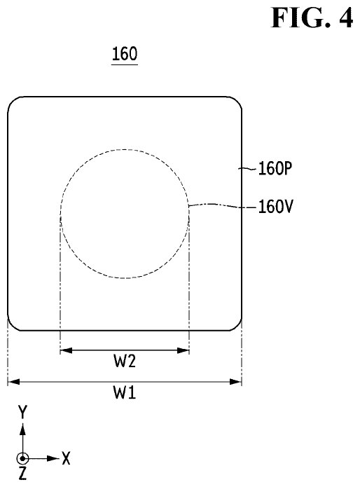

FIG. 1 is a schematic exploded perspective view for illustrating a semiconductor device according to some embodiments. FIG. 2 is a schematic cross-sectional view for illustrating the semiconductor device of FIG. 1. FIG. 3 is an enlarged view for illustrating a region R of FIG. 2. FIG. 4 is an illustrative plan view for illustrating a first pad structure of FIG. 3.

Referring to FIGS. 1 to 4, the semiconductor device according to some embodiments includes a first semiconductor chip 100 and a second semiconductor chip 200.

The first semiconductor chip 100 and the second semiconductor chip 200 may be bonded to each other in a first direction Z. For example, the first semiconductor chip 100 and the second semiconductor chip 200 may form a bonding surface (e.g., BS of FIG. 3) extending along a horizontal plane (e.g., an XY plane) that intersects the first direction Z. The first semiconductor chip 100 and the second semiconductor chip 200 may be electrically connected to each other. The first semiconductor chip 100 and the second semiconductor chip 200 may be bonded at a wafer-level, such as a wafer-to-wafer bonding manner or a chip-to-wafer bonding manner, or may be bonded at a chip-level, such as a chip-to-chip bonding manner.

Each of the first semiconductor chip 100 and the second semiconductor chip 200 may be an integrated circuit (IC) in which hundreds to millions of semiconductor elements are integrated into a single chip. The integrated circuit may be, for example, but not limited to, a logic chip such as an AP (Application Processor), a micro-processor, a CPU (Central Processing Unit), a controller, an ASIC (Application Specific Integrated Circuit), an analog element, and a digital signal processor; and/or a memory chip such as a DRAM chip, an SRAM chip, an MRAM chip, a PRAM chip, a flash memory chip, and/or a HBM (High Bandwidth Memory) chip.

As an example, the second semiconductor chip 200 may be a memory chip including memory cells such as a DRAM or a flash memory, and the first semiconductor chip 100 may be a logic chip including a peripheral circuit or the like that controls the operation of the memory cells of the second semiconductor chip 200.

As another example, the second semiconductor chip 200 may be a sensor chip that captures an image of a subject, such as a CMOS (Complementary Metal Oxide Semiconductor) image sensor, and the first semiconductor chip 100 may be a logic chip that reads an image signal from the second semiconductor chip 200 and performs various signal processing on the read image signal.

The first semiconductor chip 100 may include a first substrate 110, a first semiconductor element layer 120, a first inter-wiring insulating film 130, a first wiring structure 140, a first bonding insulating film 150, and a first pad structure 160.

The first substrate 110 may be, for example, bulk silicon or silicon-on-insulator (SOI). The first substrate 110 may be a silicon substrate or may include other materials, for example, silicon germanium, indium antimonide, lead telluride, indium arsenide, indium phosphide, gallium arsenide or gallium antimonide. Alternatively, the first substrate 110 may be a substrate in which an epitaxial layer is formed on a base substrate.

The first substrate 110 may include a first front side 110a and a first back side 110b that are opposite to each other. The first front side 110a may be an active surface on which semiconductor elements are formed. For example, the first front side 110a may include a conductive region, for example, a well doped with impurities. The first front side 110a may also include various element separation structures, such as an insulating region, for example, a shallow trench isolation (STI), that separate the conductive regions.

The first semiconductor element layer 120 may be formed on the first front side 110a of the first substrate 110. The first semiconductor element layer 120 may include various types of individual devices and/or interlayer insulating films. The individual devices may include various microelectronic devices, for example, but not limited to, a MOSFET (metal-oxide-semiconductor field effect transistor), such as a CMOS transistor (complementary metal-insulator-semiconductor transistor); a system LSI (large scale integration); a memory such as a flash memory, a DRAM, a SRAM, an EEPROM, a PRAM, a MRAM, and a RRAM; an image sensor such as a CIS (CMOS imaging sensor); a MEMS (micro-electro-mechanical system); and/or various other active or passive elements, and the like.

The first inter-wiring insulating film 130 may be formed on the first semiconductor element layer 120. The first inter-wiring insulating film 130 may cover the first semiconductor element layer 120. The first inter-wiring insulating film 130 may include, for example, but not limited to, at least one of silicon oxide, silicon nitride, silicon oxynitride, silicon oxycarbide, silicon boron nitride, silicon boron carbonitride, silicon oxycarbonitride, a low dielectric constant material having a dielectric constant smaller than silicon oxide, and/or a combination thereof. The low dielectric constant material may include, for example, at least one of FOX (Flowable Oxide), TOSZ (Torene SilaZene), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, porous polymeric material, and combinations thereof.

The first wiring structure 140 may be formed in the first inter-wiring insulating film 130. The first wiring structure 140 is connected to the first semiconductor element layer 120, and may be electrically connected to individual devices of the first semiconductor element layer 120. The first wiring structure 140 may include first wiring patterns 140M of a multi-layer structure, and first via patterns 140V that interconnect the first wiring patterns 140M of different layers from each other. The number of layers, the number, the shape, the placement, and the like of the first wiring structure 140 are merely illustrative and are not limited to those shown in the drawings.

In some embodiments, the first wiring structure 140 may include a first wiring barrier conductive film 142 and a first wiring filling conductive film 144 that are stacked in sequence. The first wiring barrier conductive film 142 may include a metal or a metal nitride for preventing the diffusion of elements included in the first wiring filling conductive film 144. The first wiring filling conductive film 144 may fill a space above the first wiring barrier conductive film 142.

The first wiring barrier conductive film 142 may include, for example, but not limited to, at least one of titanium (Ti), tantalum (Ta), tungsten (W), nickel (Ni), cobalt (Co), platinum (Pt), alloys thereof, nitrides thereof, and/or combinations thereof.

The first wiring filling conductive film 144 may include, for example, but not limited to, at least one of aluminum (Al), copper (Cu), tungsten (W), molybdenum (Mo), cobalt (Co), ruthenium (Ru), and/or alloys thereof.

The first bonding insulating film 150 may be formed on the first inter-wiring insulating film 130 and the first wiring structure 140. The first bonding insulating film 150 may extend along an upper surface of the first inter-wiring insulating film 130. The first bonding insulating film 150 may include, for example, but not limited to, a film quality of a silicon oxide series, a silicon nitride series, and/or a polymer series. As an example, the first bonding insulating film 150 may include a silicon carbonitride film (SiCN).

The first pad structure 160 may be formed on the first inter-wiring insulating film 130 and the first wiring structure 140. The first pad structure 160 penetrates the first bonding insulating film 150, and may be connected to the first wiring structure 140.

In some embodiments, an aspect ratio of the first pad structure 160 may be about 2 to about 10. Here, the aspect ratio refers to a ratio of a height in a vertical direction (e.g., the first direction Z) to a width in a horizontal direction (e.g., a second direction X or a third direction Y). For example, the first pad structure 160 may have a first height H1 in the first direction Z. The first height H1 may be defined as a distance between the lowermost surface of the first pad structure 160 and the uppermost surface of the first pad structure 160 in the first direction Z. The first pad structure 160 may also have a first width W1 in the second direction X. The first width W1 may be defined, for example, on the basis of the uppermost surface of the first pad structure 160. In this case, a ratio H1/W1 of the first height H1 to the first width W1 may be about 2 to about 10, or about 3 to about 8, or about 4 to about 6. The aspect ratio of the first pad structure 160 has been described as only being defined on the basis of the uppermost surface of the first pad structure 160, but this is merely illustrative, and the aspect ratio of the first pad structure 160 may be defined on the basis of other portions (e.g., the lowermost surface) of the first pad structure 160.

In some embodiments, the first pad structure 160 may include a first bonding pad 160P and a first pad via 160V.

The first bonding pad 160P may form a bonding surface BS between the first semiconductor chip 100 and the second semiconductor chip 200. For example, as shown in FIG. 3, a pad trench 160Pt extending from the bonding surface BS between the first semiconductor chip 100 and the second semiconductor chip 200 toward the first wiring structure 140 may be formed in the first bonding insulating film 150 and the first inter-wiring insulating film 130. The first bonding pad 160P may fill the pad trench 160Pt.

Although the first bonding pad 160P is shown only as being a square from a planar viewpoint in FIG. 4, this is merely illustrative. It goes without saying that the shape of the first bonding pad 160P may take various forms, such as a circle, an ellipse, or another polygon from the planar viewpoint.

The first pad via 160V may extend from the first bonding pad 160P, and may be connected to the first wiring structure 140. For example, a via trench 160Vt extending from the lower surface of the pad trench 160Pt and connected to the first wiring structure 140 may be formed in the first inter-wiring insulating film 130. The first pad via 160V may fill the via trench 160Vt. The first bonding pad 160P may be electrically connected to the first wiring structure 140 through the first pad via 160V.

Although the first pad via 160V is only shown as being circular from the planar viewpoint in FIG. 4, this is merely illustrative. It goes without saying that the shape of the first pad via 160V may take various forms, such as an ellipse, a square, or other polygons from the planar viewpoint.

In some embodiments, as shown in FIG. 3, the first inter-wiring insulating film 130 may include a first sub-insulating film 131, a first etch stop film 132, a second sub-insulating film 133, a first etch stop film 134, and a third sub-insulating film 135, which are stacked in sequence.

The first wiring structure 140 may be formed in the first sub-insulating film 131. The first etch stop film 132 may extend along the upper surface of the first sub-insulating film 131 and the upper surface of the first wiring structure 140. The second sub-insulating film 133 may cover the upper surface of the first etch stop film 132. The second etch stop film 134 may extend along the upper surface of the second sub-insulating film 133. The third sub-insulating film 135 may cover the upper surface of the second etch stop film 134. The first bonding insulating film 150 may extend along the upper surface of the third sub-insulating film 135.

The first etch stop film 132 may be provided as an etch stop film in an etching process for forming the first pad via 160V. For example, the via trench 160Vt penetrates the second sub-insulating film 133 and the first etch stop film 132, and may be connected to the first wiring structure 140.

In some embodiments, the width of the first pad via 160V may decrease toward the first wiring structure 140. This may be due to the characteristics of the etching process for forming the via trench 160Vt.

The second etch stop film 134 may be provided as an etch stop film in the etching process for forming the first bonding pad 160P. For example, the pad trench 160Pt penetrates the first bonding insulating film 150, the third sub-insulating film 135, and the second etch stop film 134, and may be connected to the via trench 160Vt.

In some embodiments, the width of the first bonding pad 160P may decrease toward the first wiring structure 140. This may be due to the characteristics of the etching process for forming the pad trench 160Pt.

Each of the first sub-insulating film 131, the second sub-insulating film 133 and the third sub-insulating film 135 may include, for example, but not limited to, at least one of silicon oxide, silicon nitride, silicon oxynitride, silicon oxycarbide, silicon boron nitride, silicon boron carbonitride, silicon oxycarbonitride, a low dielectric constant material having a dielectric constant smaller than silicon oxide, and/or a combination thereof.

Each of the first etch stop film 132 and the second etch stop film 134 may include, for example, but not limited to, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), silicon carbonitride (SiCN), aluminum nitride (AlN), aluminum oxide (AlO), and combinations thereof.

In some embodiments, the width of the first pad via 160V may be smaller than the width of the first bonding pad 160P. For example, the second width W2 of the first pad via 160V may be smaller than the third width W3 of the first bonding pad 160P on the basis of an interface (e.g., the upper surface of the second sub-insulating film 133) between the first pad via 160V and the first bonding pad 160P.

The first pad structure 160 may include a first barrier conductive film 162, a first filling conductive film 164, and a second filling conductive film 166 that are sequentially stacked (e.g., disposed) in the pad trench 160Pt and the via trench 160Vt.

The first barrier conductive film 162 may extend along the side surface and the lower surface of the pad trench 160Pt and the side surface and the lower surface of the via trench 160Vt. For example, the first barrier conductive film 162 may extend conformally along a profile of the pad trench 160Pt and a profile of the via trench 160Vt.

In some embodiments, the first barrier conductive film 162 may form a bonding surface BS between the first semiconductor chip 100 and the second semiconductor chip 200. For example, the uppermost surface of the first barrier conductive film 162 may be disposed coplanar with a surface (e.g., an upper surface) of the first bonding insulating film 150.

The first barrier conductive film 162 may include a metal or a metal nitride for preventing diffusion of elements included in the first filling conductive film 164 and/or the second filling conductive film 166. For example, the first barrier conductive film 162 may include, but not limited to, at least one of titanium (Ti), tantalum (Ta), tungsten (W), nickel (Ni), cobalt (Co), platinum (Pt), alloys thereof, nitrides thereof, and/or combinations thereof. As an example, the first barrier conductive film 162 may include at least one of a titanium nitride film (TiN) and/or a tantalum nitride film (TaN).

The first filling conductive film 164 may be formed on the first barrier conductive film. The first filling conductive film 164 may be interposed between the first barrier conductive film 162 and the second filling conductive film 166. The first filling conductive film 164 may fill at least a part of the region of the via trench 160Vt that is left after the first barrier conductive film 162 is filled. For example, the first filling conductive film 164 may fill a part (e.g., a lower part) of the pad trench 160Pt and the via trench 160Vt.

The second filling conductive film 166 may be formed on the first filling conductive film 164. The second filling conductive film 166 may fill at least a part of the region of the via trench 160Vt and/or the region of the pad trench 160Pt that are left after the first barrier conductive film 162 and the first filling conductive film 164 are filled. For example, the second filling conductive film 166 may fill another part (e.g., an upper part) of the pad trench 160Pt.

In some embodiments, the first filling conductive film 164 may include a first portion 164a and a second portion 164b.

The first portion 164a of the first filling conductive film 164 may overlap the second filling conductive film 166 in the first direction Z. For example, the first portion 164a of the first filling conductive film 164 may be disposed on the lower surface of the second filling conductive film 166. The first portion 164a of the first filling conductive film 164 may be interposed between the first barrier conductive film 162 and the second filling conductive film 166 in the first direction Z.

The second portion 164b of the first filling conductive film 164 may overlap the second filling conductive film 166 in the second direction X or the third direction Y. For example, the second portion 164b of the first filling conductive film 164 may extend from the first portion 164a of the first filling conductive film 164 and surround the side surface of the second filling conductive film 166. The second portion 164b of the first filling conductive film 164 may be interposed between the first barrier conductive film 162 and the second filling conductive film 166 in the second direction X or the third direction Y.

In some embodiments, the thickness of the first portion 164a of the first filling conductive film 164 may be greater than the thickness of the second portion 164b of the first filling conductive film 164. For example, the first portion 164a of the first filling conductive film 164 may have a second height H2 in the first direction Z. The second height H2 may be defined as, for example, a distance between the lowermost surface of the first portion 164a in the first direction Z and the lowermost surface of the second filling conductive film 166. In addition, the second portion 164b of the first filling conductive film 164 may have a first thickness TH in the second direction X. In this case, the second height H2 may be greater than the first thickness TH.

In some embodiments, the first thickness TH of the second portion 164b of the first filling conductive film 164 may be about 10 nm or less. For example, the first thickness TH of the second portion 164b of the first filling conductive film 164 may be about 0.1 nm to about 10 nm, or about 1 nm to about 10 nm, or about 1 nm to about 5 nm.

In some embodiments, the first filling conductive film 164 may form a bonding surface BS between the first semiconductor chip 100 and the second semiconductor chip 200. For example, the uppermost surface of the second portion 164b may be disposed coplanar with the surface (e.g., the upper surface) of the first bonding insulating film 150.

In some embodiments, the second filling conductive film 166 may form a bonding surface BS between the first semiconductor chip 100 and the second semiconductor chip 200. For example, the uppermost surface of the second filling conductive film 166 may be disposed coplanar with the surface (e.g., the upper surface) of the first bonding insulating film 150.

The first filling conductive film 164 may include a first metal element. The second filling conductive film 166 may include a second metal element. A gap-fill capability of the first metal element may be superior to the gap-fill capability of the second metal element. Here, the gap-fill capability refers to the ability of a material to fill a narrow space, such as a trench of a high aspect ratio, without defects such as a seam or a void. Here, the seam refers to a boundary line or an interface formed inside the material in the process of filling the narrow space. Here, the void refers to an empty space or an air gap formed inside the material in the process of filling the narrow space. As an example, the second metal element may be copper (Cu). In this case, the first metal element may be one of cobalt (Co), ruthenium (Ru), nickel (Ni), molybdenum (Mo), aluminum (Al) and/or tungsten (W), which are known to have better gap-fill capability than copper (Cu).

The electrical conductivity of the second filling conductive film 166 may be higher than the electrical conductivity of the first filling conductive film 164. For example, the first metal element may be cobalt (Co). In this case, the second metal element may be one of silver (Ag), copper (Cu), gold (Au), aluminum (Al) and/or tungsten (W).

In some embodiments, the first metal element may be one selected from the group including cobalt (Co), ruthenium (Ru), nickel (Ni), molybdenum (Mo), aluminum (Al) and tungsten (W), and the second metal element may be copper (Cu). As an example, the first metal element may be cobalt (Co) and the second metal element may be copper (Cu).

In some embodiments, the first filling conductive film 164 may not include a seam and/or a void. For example, the first barrier conductive film 162 and the first filling conductive film 164 may completely fill the via trench 160Vt.

In some embodiments, the second filling conductive film 166 may not include a seam and/or a void. For example, the first barrier conductive film 162, the first filling conductive film 164, and the second filling conductive film 166 may completely fill the pad trench 160Pt.

In some embodiments, a ratio of the thickness of the first portion 164a of the first filling conductive film 164 to the thickness of the second filling conductive film 166 in the first direction Z may be about 1:4 to about 3:2. For example, the second filling conductive film 166 may have a third height H3 in the first direction Z. For example, the third height H3 may be defined as a distance between the lowermost surface of the second filling conductive film 166 and the uppermost surface of the second filling conductive film 166 in the first direction Z. In this case, a ratio (H2:H3) of the second height H2 to the third height H3 may be about 1:4 to about 3:2. In the above range, the occurrence of defects such as a seam and a void in the first filling conductive film 164 and/or the second filling conductive film 166 may be prevented. In addition, in the above range, the first pad structure 160 having excellent electrical characteristics may be provided due to the high electrical conductivity of the second filling conductive film 166.

In some embodiments, the second height H2 may be smaller than or equal to the third height H3. For example, the ratio (H2:H3) of the second height H2 to the third height H3 may be about 1:4 to about 1:1. In such a case, the first pad structure 160 having excellent electrical characteristics may be provided.

The second semiconductor chip 200 may include a second substrate 210, a second semiconductor element layer 220, a second inter-wiring insulating film 230, a second wiring structure 240, a second bonding insulating film 250, and a second pad structure 260.

The second substrate 210 may include a second front side 210a and a second back side 210b that are opposite to each other. The second front side 210a may be opposite to the first front side 110a of the first substrate 110. The second substrate 210 may be the same as or similar to the first substrate 110, and therefore the detailed explanation thereof will not be provided.

The second semiconductor element layer 220 may be formed on the second front side 210a of the second substrate 210. The second semiconductor element layer 220 may be the same as or similar to the first semiconductor element layer 120, and therefore the detailed explanation thereof will not be provided.

The second semiconductor element layer 220 may include the same type of individual devices as the first semiconductor element layer 120, or may include different type of individual devices from the first semiconductor element layer 120.

As an example, the second semiconductor element layer 220 may include a memory such as a DRAM or a flash memory, and the first semiconductor element layer 120 may include a transistor or the like that controls the operation of the second semiconductor element layer 220.

As another example, the second semiconductor element layer 220 may include an image sensor such as a CIS (CMOS imaging sensor), and the first semiconductor element layer 120 may include a transistor that controls the operation of the second semiconductor element layer 220.

The second inter-wiring insulating film 230 may be formed on the second semiconductor element layer 220. In some embodiments, as shown in FIG. 3, the second inter-wiring insulating film 230 may include a fourth sub-insulating film 231, a third etch stop film 232, a fifth sub-insulating film 233, a third etch stop film 234, and a sixth sub-insulating film 235, which are stacked in sequence. The second inter-wiring insulating film 230 may be the same as or similar to the first inter-wiring insulating film 130, and therefore the detailed explanation thereof will not be provided.

The second wiring structure 240 may be formed in the second inter-wiring insulating film 230. The second wiring structure 240 is connected to the second semiconductor element layer 220, and may be electrically connected to individual devices of the second semiconductor element layer 220. The second wiring structure 240 may include second wiring patterns 240M having a multi-layer structure, and second via patterns 240V that interconnect the second wiring patterns 240M of different layers from each other. The number of layers, the number, the shape, the placement, and the like of the second wiring structures 240 are merely illustrative and are not limited to those shown in the drawings.

In some embodiments, the second wiring structure 240 may include a second wiring barrier conductive film 242 and a second wiring filling conductive film 244, which are stacked (e.g., disposed) in sequence. Each of the second wiring barrier conductive film 242 and the second wiring filling conductive film 244 may be the same as or similar to the first wiring barrier conductive film 142 and the first wiring filling conductive film 144, and therefore the detailed explanation thereof will not be provided.

The second bonding insulating film 250 may be formed on the second inter-wiring insulating film 230 and the second wiring structure 240. The second bonding insulating film 250 may be the same as or similar to the first bonding insulating film 150, and therefore the detailed explanation thereof will not be provided.

The second bonding insulating film 250 may be bonded to the first bonding insulating film 150 in the first direction Z. For example, the surface (e.g., the upper surface) of the first bonding insulating film 150 and the surface (e.g., the lower surface) of the second bonding insulating film 250 may be bonded to each other to form the bonding surface BS between the first semiconductor chip 100 and the second semiconductor chip 200.

The second pad structure 260 may be formed on the second inter-wiring insulating film 230 and the second wiring structure 240. The second pad structure 260 penetrates the second bonding insulating film 250, and may be connected to the second wiring structure 240.

The second pad structure 260 may be bonded to the first pad structure 160 in the first direction Z. For example, the surface (e.g., upper surface) of the first pad structure 160 and the surface (e.g., lower surface) of the second pad structure 260 may be bonded to each other to form the bonding surface BS between the first semiconductor chip 100 and the second semiconductor chip 200.

In some embodiments, the second pad structure 260 may include a second bonding pad 260P and a second pad via 260V. Each of the second bonding pad 260P and the second pad via 260V may be the same or similar to the first bonding pad 160P and the first pad via 160V, and therefore the detailed explanation thereof will not be provided.

The second pad structure 260 may include a second barrier conductive film 262, a third filling conductive film 264, and a fourth filling conductive film 266, which are stacked in sequence. Each of the second barrier conductive film 262, the third filling conductive film 264, and the fourth filling conductive film 266 may be the same as or similar to the first barrier conductive film 162, the first filling conductive film 164, and the second filling conductive film 166, and therefore the detailed explanation thereof will not be provided.

As electronic products are required to be miniaturized, the aspect ratio of the bonding pad in the bonding structure is constantly increasing. Therefore, there is a problem that defects such as a seam and a void occur in the bonding pad, resulting in a decrease in yield. For example, in the case of copper (Cu), which has relatively poor gap-fill capability as a material of the bonding pad, there is a high risk of an occurrence of defects such as a seam and a void in the process of forming a bonding pad of a high aspect ratio. As a result, cobalt (Co), which has relatively excellent gap-fill capability, has been researched as a bonding pad material, but cobalt (Co) or the like has a problem of having relatively low electrical conductivity.

The semiconductor device according to some embodiments may prevent defects in the first pad structure 160, using the first filling conductive film 164 and the second filling conductive film 166 having different characteristics from each other. Specifically, as explained above, the first filling conductive film 164 has a relatively excellent gap-fill capability, and therefore, the occurrence of defects such as a seam and a void in the via trench 160Vt and/or the pad trench 160Pt may be prevented. In addition, the second filling conductive film 166 has a relatively high electrical conductivity, and therefore, the low electrical conductivity of the first filling conductive film 164 may be compensated for to improve the electrical characteristics of the first pad structure 160.

Further, as explained above, the thickness (e.g., H2 of FIG. 3) of the first portion 164a of the first filling conductive film 164 may be greater than the thickness (e.g., TH of FIG. 3) of the second portion 164b of the first filling conductive film 164. As a result, the second filling conductive film 166 on the first filling conductive film 164 may have a relatively low aspect ratio, and therefore, the occurrence of defects such as a seam or a void in the second filling conductive film 166 may be prevented. As a result, a semiconductor device with improved yield and performance may be provided.

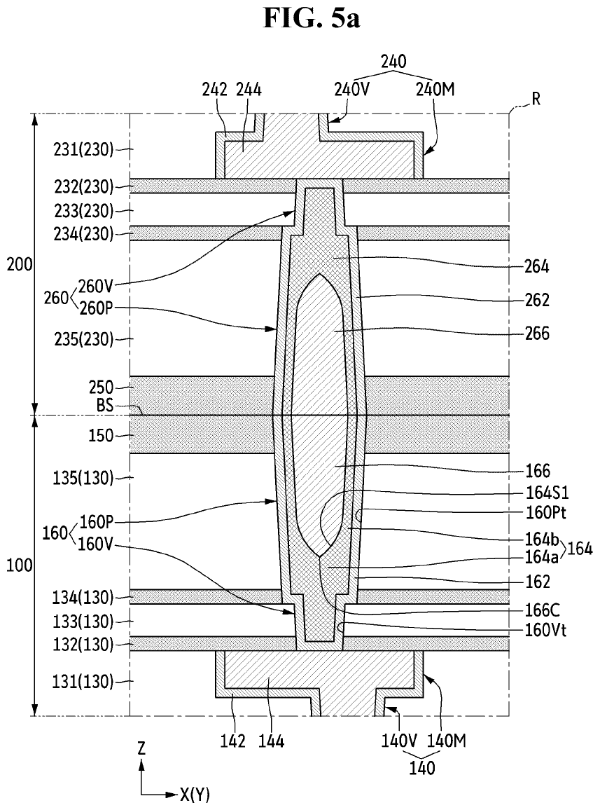

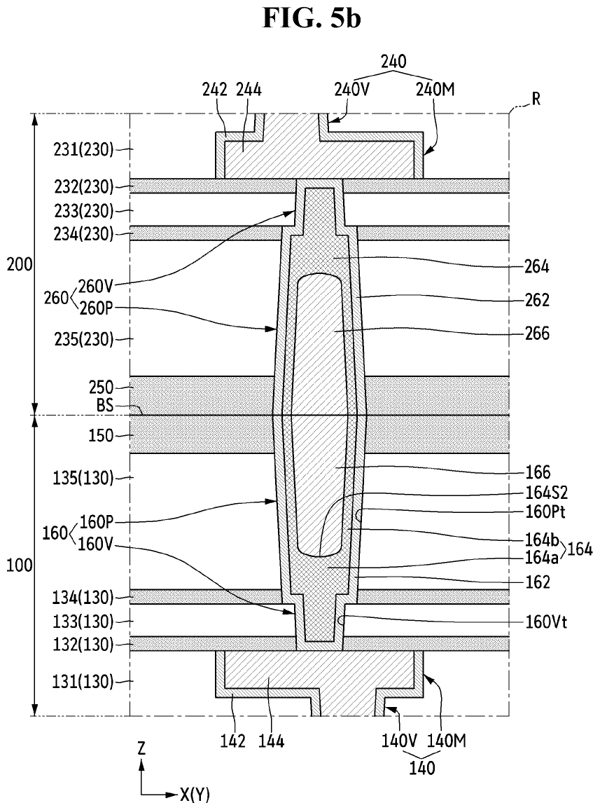

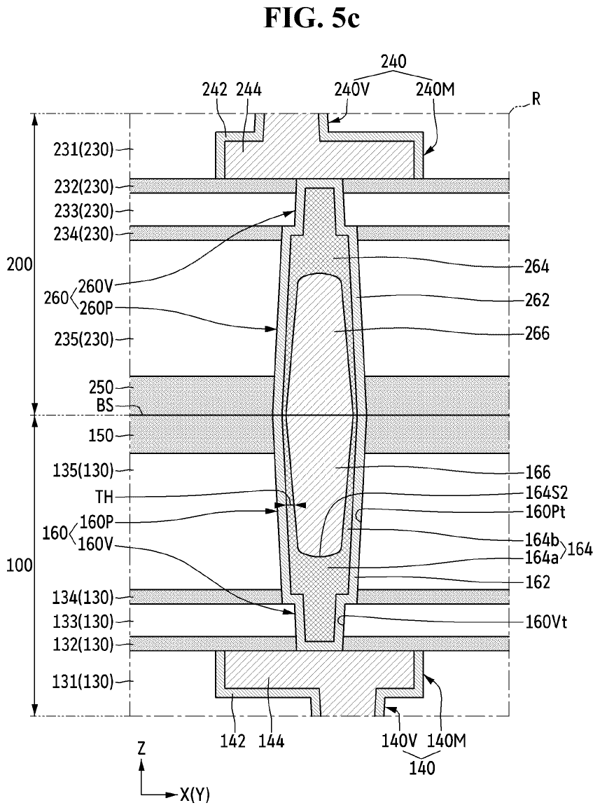

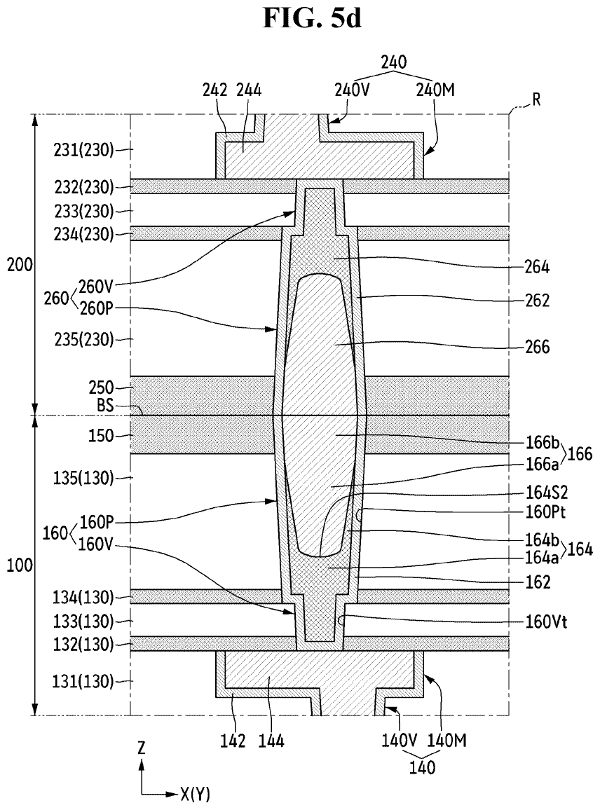

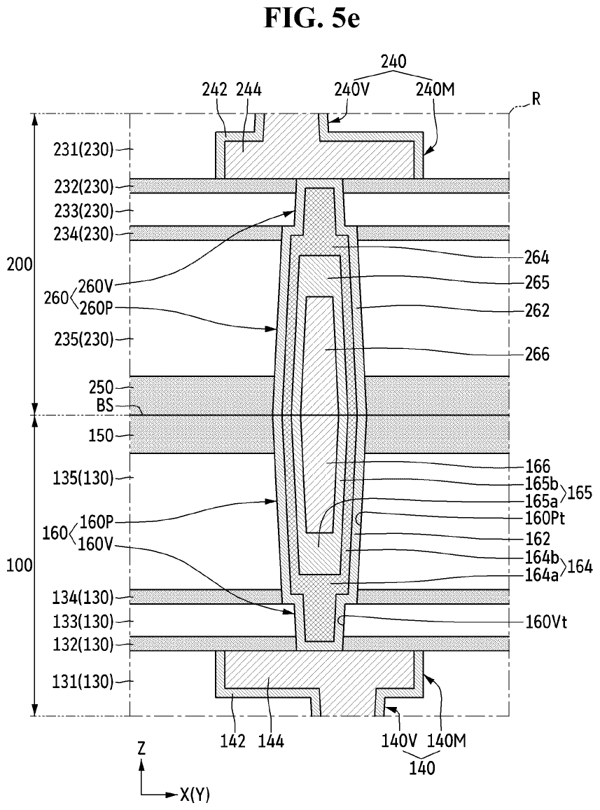

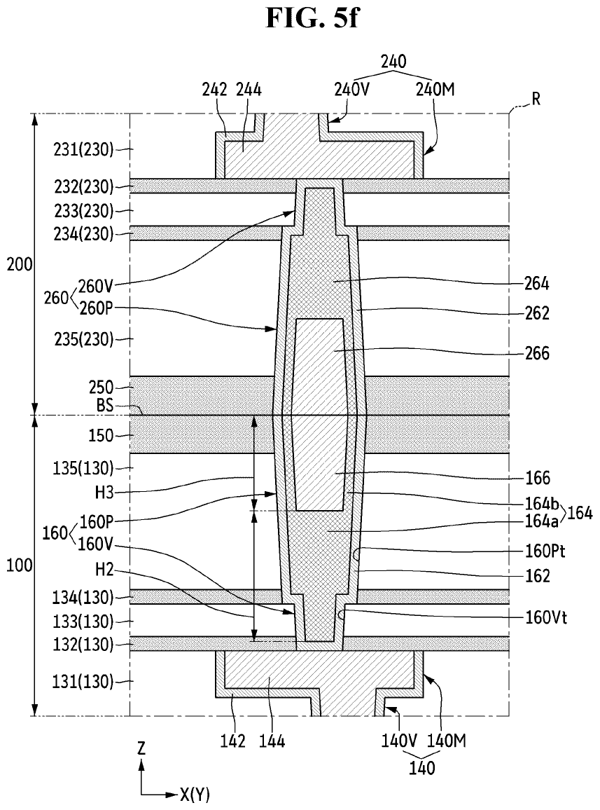

FIGS. 5a to 5f are enlarged views illustrating various alternative configurations of the region R of FIG. 2. For convenience of illustration, repeated parts of contents explained above with respect to FIGS. 1 to 4 will be briefly explained or omitted to avoid redundancy.

Referring to FIGS. 1, 2, and 5a, in the semiconductor device according to some embodiments, the second filling conductive film 166 includes an apex 166C.

For example, the second portion 164b of the first filling conductive film 164 may include an inner surface 164S1 opposite to the second filling conductive film 166. An inclination of the inner surface 164S1 of the second portion 164b to a horizontal plane (e.g., the XY plane) may decrease toward the first wiring structure 140. Furthermore, at the lowermost part of the second portion 164b, the inclination of the inner surface 164S1 of the second portion 164b to the horizontal plane (e.g., the XY plane) may not be zero (that is, the inner surface 164S1 of the second portion 164b may not be parallel to the horizontal plane (e.g., the XY plane). The second filling conductive film 166 may fill the space on the inner surface 164S1 of the second portion 164b. Thus, the lower part of the second filling conductive film 166 may include a cusp 166C pointed toward the first wiring structure 140.

Referring to FIGS. 1, 2, and 5b, in the semiconductor device according to some embodiments, the upper surface of the first portion 164a of the first filling conductive film 164 includes a concave surface 164S2 that is recessed toward the second filling conductive film 166.

For example, the inclination of the upper surface of the first portion 164a to the horizontal plane (e.g., the XY plane) may decreases as it goes away from the second portion 164b, and then may be zero (that is, the upper surface of the central part of the first portion 164a may be parallel to the horizontal plane (e.g., the XY plane)). The second filling conductive film 166 may fill the space on the concave surface 164S2 of the first portion 164a. Thus, the lower part of the second filling conductive film 166 may include a convex surface that is convex toward the first wiring structure 140.

Referring to FIGS. 1, 2, and 5c, in the semiconductor device according to some embodiments, a thickness TH of the second portion 164b of the first filling conductive film 164 decreases toward the bonding surface BS.

For example, the thickness TH of the second portion 164b adjacent to the surface (e.g., the upper surface) of the first bonding insulating film 150 may be smaller than the thickness TH of the second portion 164b adjacent to the first portion 164a of the first filling conductive film 164.

Referring to FIGS. 1, 2, and 5d, in the semiconductor device according to some embodiments, the second filling conductive film 166 includes a third portion 166a and a fourth portion 166b.

The third portion 166a of the second filling conductive film 166 may be disposed on the upper surface of the first portion 164a of the first filling conductive film 164 and on the inner surface of the second portion 164b of the first filling conductive film 164. The second portion 164b of the first filling conductive film 164 may be interposed between the third portion 166a of the second filling conductive film 166 and the first barrier conductive film 162. The third portion 166a of the second filling conductive film 166 may be spaced apart from the first barrier conductive film 162 by the second portion 164b of the first filling conductive film 164 in the horizontal direction (e.g., the second direction X or the third direction Y).

The fourth portion 166b of the second filling conductive film 166 may be disposed on the third portion 166a of the second filling conductive film 166. The second portion 164b of the first filling conductive film 164 may not be interposed between the fourth portion 166b of the second filling conductive film 166 and the first barrier conductive film 162. For example, the fourth portion 166b of the second filling conductive film 166 may be brought into direct contact with the first barrier conductive film 162 in the horizontal direction (e.g., the second direction X or the third direction Y). The first filling conductive film 164 may be spaced apart from the bonding surface BS between the first semiconductor chip 100 and the second semiconductor chip 200 in the first direction Z.

Referring to FIGS. 1, 2 and 5e, in the semiconductor device according to some embodiments, the first pad structure 160 further includes a fifth filling conductive film 165.

The fifth filling conductive film 165 may be interposed between the first filling conductive film 164 and the second filling conductive film 166. In some embodiments, the fifth filling conductive film 165 may include a fifth portion 165a and a sixth portion 165b.

The fifth portion 165a of the fifth filling conductive film 165 may overlap the second filling conductive film 166 in the first direction Z. For example, the fifth portion 165a of the fifth filling conductive film 165 may be disposed on the lower surface of the second filling conductive film 166. The fifth portion 165a of the fifth filling conductive film 165 may be interposed between the first portion 164a of the first filling conductive film 164 and the second filling conductive film 166 in the first direction Z.

The sixth portion 165b of the fifth filling conductive film 165 may overlap the second filling conductive film 166 in the second direction X or the third direction Y. For example, the sixth portion 165b of the fifth filling conductive film 165 may extend from the fifth portion 165a of the fifth filling conductive film 165 to surround the side surface of the second filling conductive film 166. The sixth portion 165b of the fifth filling conductive film 165 may be interposed between the second portion 164b of the first filling conductive film 164 and the second filling conductive film 166 in the second direction X or the third direction Y.

In some embodiments, the thickness of the fifth portion 165a of the fifth filling conductive film 165 in the first direction Z may be greater than the thickness of the sixth portion 165b of the fifth filling conductive film 165a in the second direction X or the third direction Y.

The fifth filling conductive film 165 may include a third metal element. In some embodiments, the gap-fill capability of the first metal element may be superior to the gap-fill capability of the third metal element, and the gap-fill capability of the third metal element may be superior to the gap-fill capability of the second metal element.

In some embodiments, the electrical conductivity of the second filling conductive film 166 may be higher than the electrical conductivity of the fifth filling conductive film 165, and the electrical conductivity of the fifth filling conductive film 165 may be higher than the electrical conductivity of the first filling conductive film 164.

In some embodiments, the first metal element may be cobalt (Co), the third metal element may be one selected from the group including nickel (Ni), molybdenum (Mo), aluminum (Al) and tungsten (W), and the second metal element may be copper (Cu).

In some embodiments, the second pad structure 260 may further include a sixth filling conductive film 265. The sixth filling conductive film 265 may be the same as or similar to the fifth filling conductive film 165, and therefore the detailed explanation thereof will not be provided.

Referring to FIGS. 1, 2, and 5f, in the semiconductor device according to some embodiments, the second height H2 of the first portion 164a of the first filling conductive film 164 is greater than or equal to the third height H3 of the second filling conductive film 166.

For example, the ratio (H2:H3) of the second height H2 to the third height H3 may be about 1:1 to about 3:2. In such a case, the first pad structure 160 having excellent gap-fill characteristics may be provided.

Hereinafter, a method for fabricating a semiconductor device according to illustrative embodiments will be described referring to FIGS. 1 to 12.

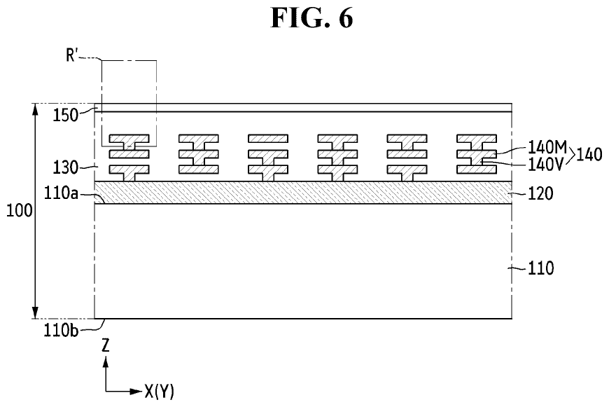

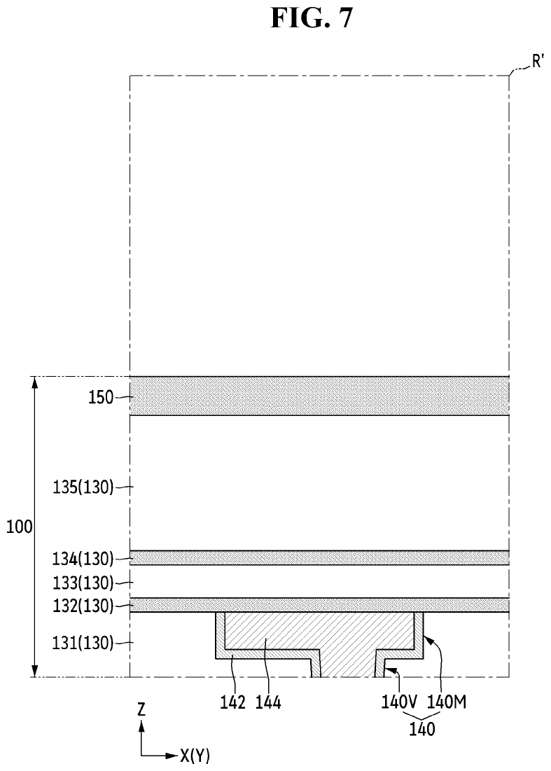

FIGS. 6 to 12 are diagrams of intermediate structures corresponding to intermediate steps of a method for fabricating a semiconductor device according to some embodiments. For convenience of explanation, repeated parts of contents explained above with respect to FIGS. 1 to 5f will be briefly explained or omitted to avoid redundancy. For reference, FIG. 7 is an enlarged view illustrating a region R′ of FIG. 6, which corresponds to the region R of FIG. 2.

Referring to FIGS. 6 and 7, a first semiconductor element layer 120, a first inter-wiring insulating film 130, a first wiring structure 140, and a first bonding insulating film 150 are formed on the first substrate 110.

The first semiconductor element layer 120 may be formed on a first front side 110a of the first substrate 110. The first inter-wiring insulating film 130 and the first wiring structure 140 may be formed on the first semiconductor element layer 120. The first wiring structure 140 may include first wiring patterns 140M and first via patterns 140V. The first bonding insulating film 150 may be formed on the first inter-wiring insulating film 130 and the first wiring structure 140.

In some embodiments, the first inter-wiring insulating film 130 may include a first sub-insulating film 131, a first etch stop film 132, a second sub-insulating film 133, a second etch stop film 134, and a third sub-insulating film 135 that are stacked in sequence.

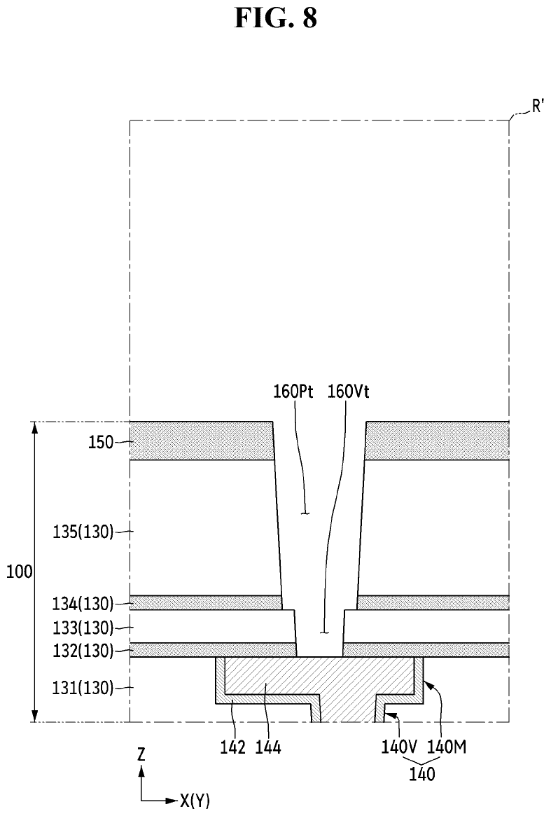

In some embodiments, the first wiring structure 140 may include a first wiring barrier conductive film 142 and a first wiring filling conductive film 144 that are stacked in sequence. Referring to FIG. 8, the pad trench 160Pt and the via trench 160Vt are formed.

For example, an etching process of using the second etch stop film 134 as an etch stop film may be performed. As a result, a pad trench 160Pt that penetrates the first bonding insulating film 150, the third sub-insulating film 135, and the second etch stop film 134 to expose the upper surface of the second sub-insulating film 133 may be formed. Next, an etching process of using the first etch stop film 132 as an etch stop film may be performed. As a result, a via trench 160Vt that penetrates the second sub-insulating film 133 and the first etch stop film 132 to expose the upper surface of the first wiring structure 140 may be formed.

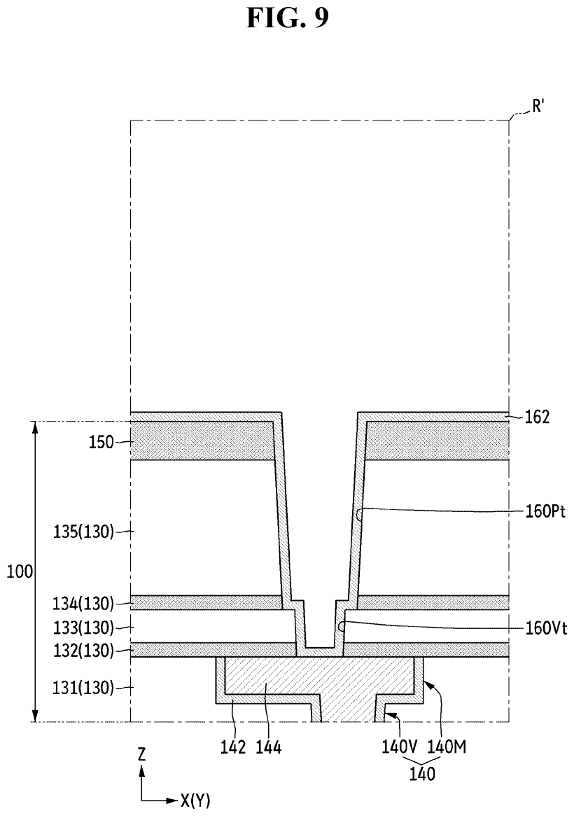

Referring to FIG. 9, the first barrier conductive film 162 is formed in the via trench 160Vt and the pad trench 160Pt.

The first barrier conductive film 162 may extend along the side surface and lower surface of the pad trench 160Pt and the side surface and lower surface of the via trench 160Vt. The first barrier conductive film 162 may extend along the upper surface of the first bonding insulating film 150. The first barrier conductive film 162 may be formed by, for example, but not limited to, a chemical vapor deposition (CVD) method, an atomic layer deposition (ALD) method, an electroplating method, or the like.

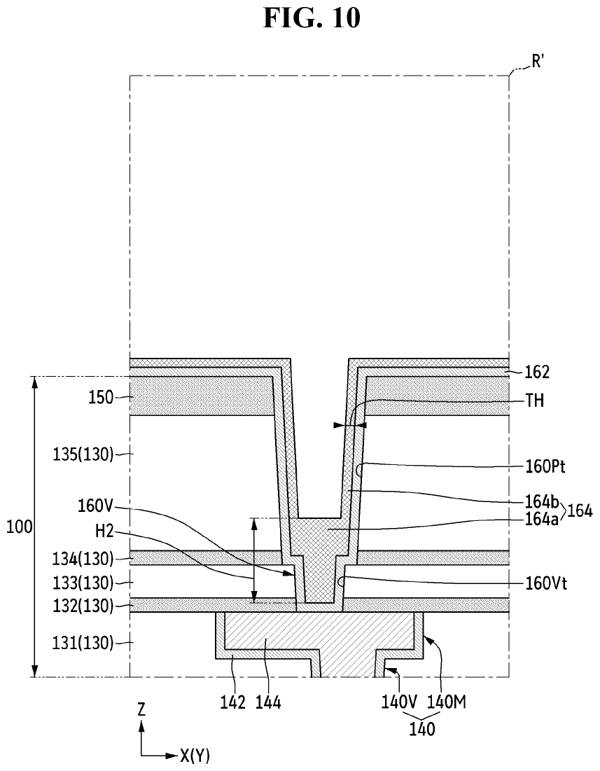

Referring to FIG. 10, the first filling conductive film 164 is formed on the first barrier conductive film 162.

The first filling conductive film 164 may fill at least a part of the via trench 160Vt and a part of the pad trench 160Pt. The first filling conductive film 164 may be formed by, for example, but not limited to, a chemical vapor deposition method, an atomic layer deposition method, an electroplating method, or the like.

In some embodiments, the first filling conductive film 164 may be formed by the electroplating method using a bottom-up filling manner. The bottom-up filling manner refers to a manner of sequentially filling the conductive metal from the bottom to the top of the narrow space to fill the narrow space, such as a trench of high aspect ratio, with a conductive metal. The bottom-up filling manner may use, but not limited to, a suppressor such as a polymer. The second height H2 of the first portion 164a of the first filling conductive film 164 may be greater than the thickness TH of the second portion 164b of the first filling conductive film 164, by using the bottom-up filling manner.

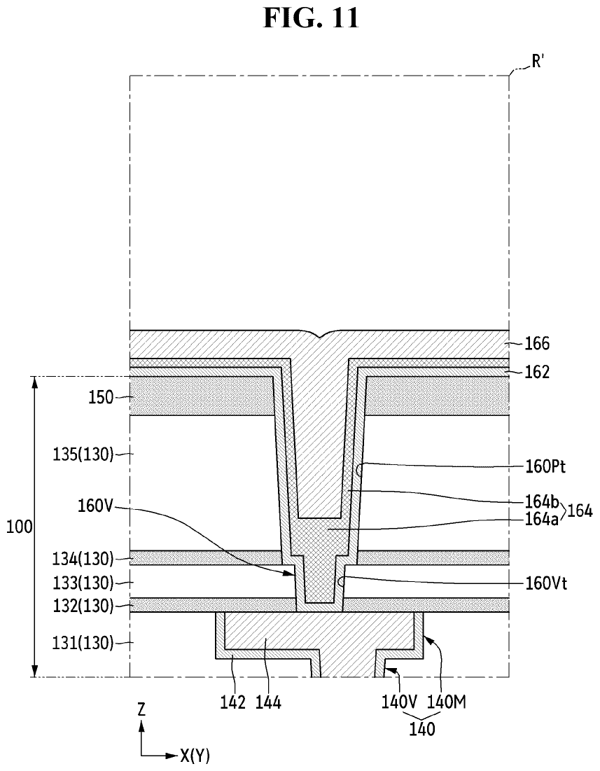

Referring to FIG. 11, the second filling conductive film 166 is formed on the first filling conductive film 164.

The second filling conductive film 166 may fill the via trench 160Vt and the pad trench 160Pt. The second filling conductive film 166 may be formed by, for example, but not limited to, a chemical vapor deposition method, an atomic layer deposition method, an electroplating method, and the like. In some embodiments, the second filling conductive film 166 may be formed by the electroplating method.

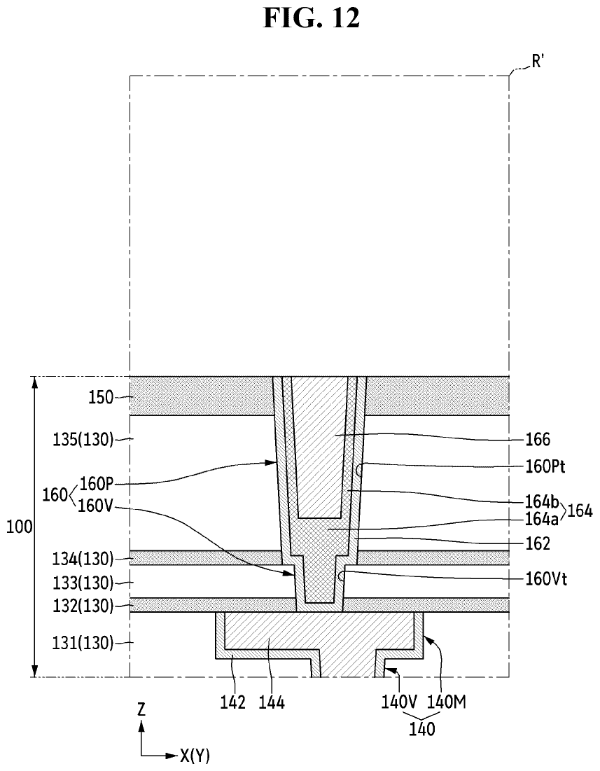

Referring to FIG. 12, a planarization process is performed on the first barrier conductive film 162, the first filling conductive film 164, and the second filling conductive film 166.

As the planarization process is performed, the upper surface of the first bonding insulating film 150 may be exposed. In addition, the first pad structure 160 including the first bonding pad 160P and the first pad via 160V may be formed. The planarization process may include, for example, but not limited to, a chemical mechanical polishing (CMP) process. Accordingly, the first semiconductor chip 100 including the first pad structure 160 may be fabricated.

Next, referring to FIG. 3, the first semiconductor chip 100 and the second semiconductor chip 200 are bonded.

The first bonding insulating film 150 of the first semiconductor chip 100 may be bonded to the second bonding insulating film 250 of the second semiconductor chip 200. The first pad structure 160 of the first semiconductor chip 100 may be bonded to the second pad structure 260 of the second semiconductor chip 200. The fabricating process of the second semiconductor chip 200 may be the same as or similar to the fabricating process of the first semiconductor chip 100, and therefore the detailed explanation thereof will not be provided. Accordingly, the semiconductor device explained above using FIGS. 1 to 4 may be fabricated.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

The term “about” is used herein to provide literal support for the exact number that it precedes, as well as a number that is near to or approximately the number that the term precedes. In determining whether a number is near to or approximately a specifically recited number, the near or approximating unrecited number may be a number, which, in the context in which it is presented, provides the substantial equivalent of the specifically recited number. It should be appreciated that all numerical values and ranges disclosed herein are approximate values and ranges, whether “about” is used in conjunction therewith. It should also be appreciated that the term “about,” as used herein, in conjunction with a numeral refers to a value that may be ±0.01% (inclusive), ±0.1% (inclusive), ±0.5% (inclusive), ±1% (inclusive) of that numeral, ±2% (inclusive) of that numeral, ±3% (inclusive) of that numeral, ±5% (inclusive) of that numeral, ±10% (inclusive) of that numeral, or ±15% (inclusive) of that numeral. It should further be appreciated that when a numerical range is disclosed herein, any numerical value falling within the range is also specifically disclosed.

What is claimed is:

1. A semiconductor device comprising:
a first semiconductor chip that includes a first substrate, a first semiconductor element layer on the first substrate, a first inter-wiring insulating film on the first semiconductor element layer, a first wiring structure in the first inter-wiring insulating film, and a first pad structure on the first wiring structure; and
a second semiconductor chip that includes a second substrate, a second semiconductor element layer on the second substrate, a second inter-wiring insulating film on the second semiconductor element layer, a second wiring structure in the second inter-wiring insulating film, and a second pad structure on the second wiring structure, wherein
the first pad structure and the second pad structure are bonded to each other in a first direction,
the first pad structure includes a first filling conductive film and a second filling conductive film that are sequentially disposed on the first wiring structure,
the first filling conductive film includes a first portion that overlaps the second filling conductive film in the first direction, and a second portion that overlaps the second filling conductive film in a second direction intersecting the first direction,
a first height of the first portion in the first direction is greater than a thickness of the second portion in the second direction, and
an electrical conductivity of the second filling conductive film is greater than an electrical conductivity of the first filling conductive film.

2. The semiconductor device of claim 1, wherein
the first semiconductor chip further includes a first bonding insulating film on the first inter-wiring insulating film,
the second semiconductor chip further includes a second bonding insulating film on the second inter-wiring insulating film, and
the first bonding insulating film and the second bonding insulating film are bonded to each other in the first direction.

3. The semiconductor device of claim 1,
wherein the first pad structure further includes a barrier conductive film extending along a side surface and a lower surface of the first portion and an outer surface of the second portion.

4. The semiconductor device of claim 1, wherein
the first inter-wiring insulating film includes a pad trench that extends from a bonding surface between the first semiconductor chip and the second semiconductor chip toward the first wiring structure, and a via trench that extends from a lower surface of the pad trench and is connected to the first wiring structure,
the first portion of the first filling conductive film fills a part of the pad trench and the via trench, and
the second portion of the first filling conductive film and the second filling conductive film fill another part of the pad trench.

5. The semiconductor device of claim 1,
wherein a gap-fill capability of a first metal element contained in the first filling conductive film is superior to a gap-fill capability of a second metal element contained in the second filling conductive film.

6. The semiconductor device of claim 5, wherein
the first metal element is selected from a group including cobalt (Co), ruthenium (Ru), nickel (Ni), molybdenum (Mo), aluminum (Al) and tungsten (W), and
the second metal element is copper (Cu).

7. The semiconductor device of claim 1,
wherein an aspect ratio of the first pad structure is 2 to 10.

8. The semiconductor device of claim 7,
wherein a width of the first pad structure is 10 nm to 120 nm at a bonding surface between the first semiconductor chip and the second semiconductor chip.

9. The semiconductor device of claim 1,
wherein a ratio of the first height of the first portion of the first filling conductive film to a second height of the second filling conductive film in the first direction is 1:4 to 3:2.

10. The semiconductor device of claim 1,
wherein the thickness of the second portion of the first filling conductive film in the second direction is 10 nm or less.

11. A semiconductor device comprising:
a first semiconductor chip that includes a first substrate, a first semiconductor element layer on the first substrate, a first inter-wiring insulating film on the first semiconductor element layer, a first wiring structure in the first inter-wiring insulating film, and a first pad structure on the first wiring structure; and
a second semiconductor chip that includes a second substrate, a second semiconductor element layer on the second substrate, a second inter-wiring insulating film on the second semiconductor element layer, a second wiring structure in the second inter-wiring insulating film, and a second pad structure on the second wiring structure, wherein
the first pad structure and the second pad structure are bonded to each other, the first pad structure includes a first filling conductive film and a second filling conductive film that are sequentially disposed on the first wiring structure,
an aspect ratio of the first pad structure is 2 to 10,
a ratio of a first height from a lowermost surface of the first filling conductive film to a lowermost surface of the second filling conductive film to a second height from the lowermost surface of the second filling conductive film to an uppermost surface of the second filling conductive film is 1:4 to 3:2, and
an electrical conductivity of the second filling conductive film is higher than that of the first filling conductive film.

12. The semiconductor device of claim 11,
wherein a width of the first pad structure is 10 nm to 120 nm at a bonding surface between the first semiconductor chip and the second semiconductor chip.

13. The semiconductor device of claim 11,
wherein a gap-fill capability of a first metal element contained in the first filling conductive film is superior to the gap-fill capability of a second metal element contained in the second filling conductive film.

14. The semiconductor device of claim 13, wherein
the first metal element is selected from a group including cobalt (Co), ruthenium (Ru), nickel (Ni), molybdenum (Mo), aluminum (Al) and tungsten (W), and
the second metal element is copper (Cu).

15. The semiconductor device of claim 11, wherein
the first semiconductor chip and the second semiconductor chip are bonded to each other in a first direction,
the first filling conductive film includes a first portion that overlaps the second filling conductive film in the first direction, and a second portion that overlaps the second filling conductive film in a second direction intersecting the first direction, and
a height of the first portion in the first direction is greater than a thickness of the second portion in the second direction.

16. A semiconductor device comprising:
a first semiconductor chip and a second semiconductor chip bonded to each other, wherein the first semiconductor chip includes:
a first substrate;
a first semiconductor element layer on the first substrate;
a first inter-wiring insulating film on the first semiconductor element layer;
a first wiring structure connected to the first semiconductor element layer, in the first inter-wiring insulating film;
a first bonding insulating film on the first inter-wiring insulating film; and
a first pad structure that penetrates the first bonding insulating film and is connected to the first wiring structure,
the second semiconductor chip includes:
a second substrate;
a second semiconductor element layer on the second substrate;
a second inter-wiring insulating film on the second semiconductor element layer;
a second wiring structure that is connected to the second semiconductor element layer, in the second inter-wiring insulating film;
a second bonding insulating film that is bonded to the first bonding insulating film, on the second inter-wiring insulating film; and
a second pad structure that penetrates the second bonding insulating film, is connected to the second wiring structure, and bonded to the first pad structure,
the first inter-wiring insulating film and the first bonding insulating film include a pad trench that extends from a bonding surface between the first semiconductor chip and the second semiconductor chip toward the first wiring structure,
the first pad structure includes a barrier conductive film extending along a profile of a side surface and a lower surface of the pad trench, a first filling conductive film that fills a part of the pad trench on the barrier conductive film, and a second filling conductive film that fills another part of the pad trench on the first filling conductive film,
a gap-fill capability of a first metal element contained in the first filling conductive film is superior to the gap-fill capability of a second metal element contained in the second filling conductive film, and
an electrical conductivity of the second filling conductive film is higher than the electrical conductivity of the first filling conductive film.

17. The semiconductor device of claim 16, wherein
the first semiconductor chip and the second semiconductor chip are bonded to each other in a first direction,
the first filling conductive film includes a first portion that overlaps the second filling conductive film in the first direction, and a second portion that overlaps the second filling conductive film in a second direction intersecting the first direction, and
a height of the first portion in the first direction is greater than a thickness of the second portion in the second direction.

18. The semiconductor device of claim 16, wherein
the first inter-wiring insulating film further includes a via trench extending from a lower surface of the pad trench and connected to the first wiring structure, and
the barrier conductive film and the first filling conductive film fill the via trench.

19. The semiconductor device of claim 16,
wherein an aspect ratio of the first pad structure is 2 to 10.

20. The semiconductor device of claim 16, wherein
the first filling conductive film includes cobalt (Co), and
the second filling conductive film includes copper (Cu).
